(19) United States
(12) Patent Application Publication
(10) Pub. No.: US 2025/0185408 A1
(43) Pub. Date: Jun. 5, 2025

(54) A Method of Manufacturing Group III-V Based Semiconductor Materials Comprising Strain Relaxed Buffers Providing Possibility for Lattice Constant Adjustment When Growing on (111)SI Substrates

(71) Applicant: Integrated Solar AS, Trondheim (NO)

(72) Inventor: Renato Bugge, Trondheim (NO)

(21) Appl. No.: 18/845,132

(22) PCT Filed: Mar. 22, 2023
(86) PCT No.: PCT/EP2023/057339

§ 371 Date: Sep. 9, 2024

(30) Foreign Application Priority Data
Mar. 22, 2022 (NO) 20220344

(51) Int. Cl. H10F 71/00; H01L 21/02; H10F 77/124

(52) U.S. Cl. CPC H10F 71/127; H01L 21/02381; H01L 21/02463; H01L 21/02466; H01L 21/02631; H10F 77/124

(57) ABSTRACT

The resent invention is related to a method of manufacturing a semiconductor material comprising group III-V materials grown on a (111)Si substrate, wherein a lattice constant of respective layers is adjustable bringing the lattice constant of the material close to or between the lattice constant of GaAs, GaSb, InAs, InSb and/or InP.

### BACKGROUND

The disclosed embodiments relate to manufacturing of group III-V based semiconductor materials with thermal evaporation sources like a Molecular Beam Epitaxy or similar techniques on a (111)Si substrate, wherein at least one buffer layer provides possibility of adjustment of at least one lattice constant.

In the field of semiconductor material science, group III-V materials are known to have many desirable properties as semiconductors. The mobility and other physical properties of these materials increase the speed of semiconductor devices made from this material significantly compared with the more traditional semiconductor materials like silicon (Si). However, Si substrates are much cheaper than GaAs, InP, GaSb, InAs, InSb and alike group III-V substrates. Therefore, manufacturing a semiconductor material combination, i.e., a semiconductor device, comprising group III-V in combination with a Si wafer support is a desirable material combination providing beneficial semiconductor properties at a beneficial cost.

However, epitaxial growth of high-quality monocrystalline group III-V in combination with monocrystalline silicon is not trivial due to the large lattice mismatch of most of the materials. When combining these materials, as known in the art, the lattice mismatch may lead to stacking of faults, denoted threading dislocations that may ruin the physical properties necessary for making semiconductor devices that fulfils desired quality requirements. The threading dislocations appear for example in an epitaxial growth of a III-V layer on top of a nucleation layer on a Si wafer. The threading dislocations will have a range of orientations relative to the epitaxial growth direction, mostly starting as interfacial misfit dislocations and propagating though the grown layers. The length of the threading dislocations may be shorter than the end thickness of the grown layer, but thickness of layers in semiconductor devices contributes significantly to what kind of physical properties the material will provide as a basis for a semiconductor device, for example how transparent an optical device can be. Even though the length of the threading dislocations may be limited, the physical property of the interface between the different materials still needs to be controllable, especially when thin buffer layers (<1 μm) comprising group III-V material is applied, which is a beneficial cost saving parameter.

It is also known that such material combinations have different thermal expansion coefficients and when a manufactured material is produced and cooled down to room temperature the surface of the material may bend. The aspect of bending of surfaces is a problem in further processing or handling of such materials.

A requirement can for example be that the Total Thickness Variation, TTV, is less than 10 μm. The TTV is a measure of the difference between the highest thickness and the lowest thickness of the substrate.

WO 2016/105211 by the same inventor discloses a method of manufacturing a semiconductor material comprising group III-V materials grown on a (111)Si substrate providing a counterbalancing of residual strain left in the manufactured material after cooling down to room temperature. The counterbalancing is achieved by growing different material layers with different lattice constants wherein the difference between the lattice constants induces a strain in the crystal structure counterbalancing the residual strain. The result is a flatter material surface of the finished and cooled material. A flat surface is an important aspect of many applications, for example in multi-junction devices.

The article «III-V-on-silicon solar cells reaching 33% photoconversion efficiency in two-terminal configuration», by R. Cariou et al., Nature Energy, Vol. 3, pp. 326 (2018) disclose how the conversion efficiency of silicon single-junction solar cells is intrinsically constrained to 29.4%, and practically limited to around 27%. It is possible to overcome this limit by combining silicon with high-bandgap materials, such as III-V semiconductors, in a multi-junction device. Significant challenges associated with this material combination have hindered the development of highly efficient III-V/Si solar cells. Here, they demonstrate a III-V/Si cell reaching similar performances to standard III-V/Ge triple-junction solar cells. This device is fabricated using wafer bonding to permanently join a GalnP/GaAs top cell with a silicon bottom cell.

The article «A Review of Ultrahigh Efficiency III-V Semiconductor Compound Solar Cells: Multijunction Tandem, Lower Dimensional, Photonic Up/Down Conversion and Plasmonic Nanometallic Structures», by K. Tanabe, Energies, Vol. 2, No. 3, pp. 504 (2009), disclose how energy conversion efficiencies around 40% have been achieved in laboratories using III-V semiconductor compounds as photovoltaic materials. This article reviews the efforts and accomplishments made for higher efficiency III-V semiconductor compound solar cells, specifically with multijunction tandem, lower-dimensional, photonic up/down conversion, and plasmonic metallic structures. Technological strategies for further performance improvement from the most efficient (Al) InGaP/(In) GaAs/Ge triple-junction cells including the search for 1.0 eV bandgap semiconductors are discussed. They point out that multilayer epitaxially grown solar cells require lattice matching among the stacked semiconductor materials.

The article «A Brief Review of High Efficiency III-V Solar Cells for Space Application», by J. Li, et al., Frontiers in Physics, Vol. 8, Article 631925 (2021) disclose how space solar cells are facing more critical challenges than before like higher conversion efficiency and better radiation resistance. Being the main power supply in spacecrafts, III-V multijunction solar cells are the focus for space application due to their high efficiency and super radiation resistance. In multijunction solar cell structures, the key to obtaining high crystal quality and increase cell efficiency is satisfying the lattice matching and bandgap matching conditions. New materials and new structures of high efficiency multijunction solar cell structures are continuously coming out with low-cost, lightweight, flexible, and high power-to-mass ratio features in recent years. In addition to the efficiency and other properties, radiation resistance is another sole criterion for space solar cells.

The article «Migration-Enhanced Epitaxy of GaAs and AlGaAs», by Y. Horikoshi, M. Kawashima and H. Yamaguchi, Japanese Journal of Applied Physics, Vol. 27, No. 2R, pp. 169 (1988) disclose how surface migration can effectively be enhanced by evaporating Ga or Al atoms onto a clean GaAs surface under an As-free or low As pressure atmosphere. This characteristic was utilized by alternately supplying Ga and/or Al and As4 to the substrate surface for growing atomically-flat GaAs—AlGaAs heterointerfaces, and also for growing high-quality GaAs and AlGaAs layers at very low substrate temperatures. The migration characteristics of surface atoms have been investigated through reflection high-energy electron diffraction measurements. It was found that different growth mechanisms are operative in this method at both high and low temperatures. Both these mechanisms are expected to yield flat heterojunction interfaces. By applying this method, GaAs layers and GaAs—AlGaAs single quantum-well structures with excellent photoluminescence were grown at substrate temperatures of 200 and 300° C., respectively.

The article «2D-3D transition in highly strained GaAs/Ga₁-xInxAs heterostructures by transmission electron microscopy» by C. Delamarre, et. al. Journal of Crystal Growth 177 (1997) 6 16 disclose an analysis of a 2D-3D transition occurring in highly strained GaAs/Ga₁_xfnxAs heterostructures when grown by MBE. The analysis was done by specific TEM techniques and correlated to photoluminescence data. HREM evidence that the transition always happens in a standard growth for x˜0.35. This leads to a purely elastic relaxation which is characterized by a sinusoidal modulation. When the temperature is decreased, it was confirmed by “average intensity profiles” recorded from digitized HREM images that the transition is pushed away towards greater thicknesses. Furthermore, when adding Te as a surfactant, 311 (g. ng) weak-beam images demonstrate that the 2D growth mode is maintained up to the plastic relaxation. The article «Ultra-Thin Monocrystalline Silicon Solar Cell with 12.2% Efficiency Using Silicon-On-Insulator Substrate» by Bian, Jian-Tao et. al. Journal of Nanoscience and Nanotechnology, Volume 15 Number 4, disclose a single side heterojunction silicon solar cell designed and fabricated using Silicon-On-Insulator (SOI) substrate. The TCAD software was used to simulate the effect of silicon layer thickness, doping concentration and the series resistance. A 10.5 μm thick monocrystalline silicon layer was epitaxially grown on the SOI with boron doping concentration of 2×10¹⁶ cm⁻³ by thermal CVD. Very high V ∝ of 678 mV was achieved by applying amorphous silicon heterojunction emitter on the front surface. The single cell efficiency of 12.2% was achieved without any light trapping structures. The rear surface recombination and the series resistance are the main limiting factors for the cell efficiency in addition to the c-Si thickness. By integrating an efficient light trapping scheme and further optimizing fabrication process, higher efficiency of 14.0% is expected for this type of cells. It can be applied to integrated circuits on a monolithic chip to meet the requirements of energy autonomous systems.

Prior art discloses different manufacturing methods regarding group III-V materials in combination with other materials. Prior art solutions often use other substrates and/or thicker buffer layers, or a super lattice, or slow growth methods etc. mitigating effects of for example lattice constant mismatch between material layers. It is therefore a need of an improved method of manufacturing group III-V materials on Si substrates, and especially for multi-junction solar cell structures with high energy conversion efficiency.

### SUMMARY

Provided herein is an alternative to the prior art.

In particular, provided herein is a semiconductor material comprising at least one layer with an adjustable lattice constant, wherein an adjusted lattice constant is close to or between the lattice constants of GaAs, InAs, InSb, GaSb or InP.

Thus, the above-described object and several other objects are intended to be obtained in a first aspect of the disclosure by providing a method of manufacturing a material comprising group III-V materials on top of a (111)Si substrate wherein the lattice constant of the material is adjustable to be close to or between the lattice constants of GaAs, InAs, InSb, GaSb or InP.

The disclosed embodiments are particularly, but not exclusively, advantageous for obtaining a method of manufacturing a semiconductor material comprising at least steps of:
using a Silicon substrate of 40-1000 μm thickness with a surface on or less than 5 degrees off the (111) crystal plane,
growing a first layer of 1-100 nm thickness comprising III-V materials on top of the Si substrate, wherein the layer is grown leaving multiple thicker grown islands connected via thinner sections of the first layer,
the thicker grown III-V islands are grown with a gradient in their lattice constant providing a lattice constant of the first layer being different from the lattice of the final grown material,
the difference in lattice constant between the first layer and the final grown material results in defect planes parallel to the (111) surface located below the grown islands, wherein the defect planes provide strain relaxation of the final grown material,
growing a second layer of 1-100 nm thickness comprising III-V materials reducing the surface roughness compared to the final surface of the first layer.

Respective aspects of disclosure may each be combined with any of the other aspects. These and other aspects will be disclosed and elucidated with reference to the embodiments described herein.

### BRIEF DESCRIPTION OF THE DRAWINGS

FIG. 1 illustrates an electron microscope image of an example of three dimensional growing in a manufactured semiconductor material.

FIG. 2 is a schematic drawing of the image illustrated in FIG. 1.

FIG. 3A illustrates another electron microscope picture of an example of a manufactured semiconductor material.

FIG. 3B illustrates a Fourier transform of the high-resolution image in FIG. 3A.

FIG. 4 illustrates an example of a solar cell according to the disclosure.

FIG. 5A illustrates a further example of a solar cell according to the disclosure.

FIG. 5B illustrates a further example of a solar cell according to the disclosure.

FIG. 6A, FIG. 6B and FIG. 6C illustrates respective steps of growing a first layer 15 and then adding a second layer 14 flattening the first layer.

### DETAILED DESCRIPTION

Although the embodiments are disclosed in connection with specific examples of embodiments, it should not be construed as being in any way limited to the presented examples. In the context of the claims, the terms “comprising” or “comprises” do not exclude other possible elements or steps. Further, the mentioning of references such as “a” or “an” etc. should not be construed as excluding a plurality. The use of reference signs in the claims with respect to elements indicated in the figures shall also not be construed as limiting the scope of the invention.

Furthermore, combining individual features mentioned in different claims may possibly be advantageously, and the mentioning of these features in different claims does not exclude that a combination of features is not possible and advantageous.

The disclosed embodiments are related to manufacturing of a semiconductor material comprising group III-V materials on a silicon substrate with a crystal orientation (111). The manufacturing can be done with different material combinations without being limited to just one lattice constant or a limited range of lattice constants.

A known advantage of using (111)Si substrates is that defects and threading dislocations in a material grown with group III-V materials are present in layers parallel to the (111)Si crystal surface, i.e., it is possible to grow thinner layers (<1 μm) with group III-V materials without lattice defects propagating upwards into the respective material layers. The publication WO 2016/105211 by the same inventor discuss this aspect of growing group III-V materials on a (111)Si substrate.

The lattice constant of (111)Si with a cubical lattice is 5,4131 Å while the most used group III-V materials with cubical lattices has lattice constants in a range varying from about 5,451 Å to about 6,479 Å. This variation in lattice constants is a challenge when combining silicon and one or more different group III-V materials.

Therefore, a prior art method is to restrict the manufacturing to one lattice constant in all layers or add thicker (>1 μm) buffer layers in between respective layers with different lattice constants. These solutions add costs to the material manufacturing. Other methods are known in prior art that also add costs to the material manufacturing.

However, when using the (111)Si substrate some of the problems with threading dislocations are mitigated as disclosed above.

With respect to solar cells, it is known in prior art that one of the limiting factors for a multi-layer solar cell is that the lattice constant of the respective cells must be close to each other when providing a high efficiency multi-layer solar cell. The alternative is to use thicker buffer layers or accept defects in the materials, which reduces the energy output from a multi-layer solar cell.

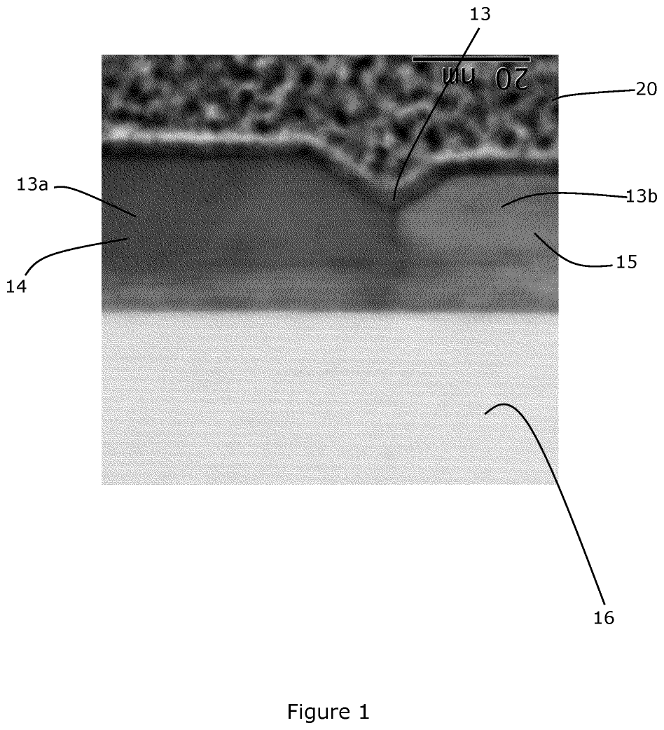

There exist also other challenges when growing group III-V materials on a Si substrate. For example, FIG. 1 illustrate a situation denoted three dimensional growths. A first layer 15 is grown on a surface of a (111)Si substrate 16 wherein two islands 13a, 13b has been created in the interface between the Si substrate surface and the first layer grown on the Si substrate surface. Such an island is typically a few nm thick. This situation is often present when growing for example a first layer on a Si(111) substrate comprising AlAsAb. The reason is that AlSb and AlAsAb does not cover a whole Si(111) substrate surface if the layer is thin (<25 nm-100 m) and growth conditions favors 3D growth. When the layer is thicker (>25 nm-100 nm) the whole surface of the substrate can be covered once growth conditions favor more 2D-like growth

According to an example of one embodiment a thinner layer 15 is of interest, i.e., <25 nm-100 nm This may leave islands on the surface but growing a further layer on top of the “islands” a flat surface can be accomplished. The total thickness of the first layer and the extra layer (second layer) can be less than a thickness of a first layer 15 grown to a thickness such that the islands are disappearing as discussed above.

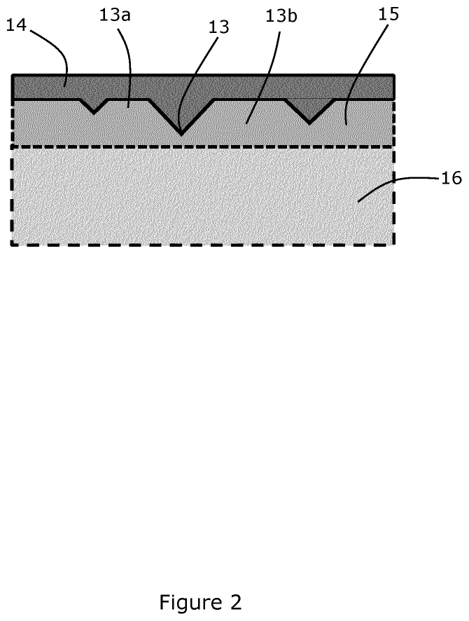

FIG. 2 is a schematic drawing of the illustrated situation wherein islands are present and wherein the islands 13a, 13b are meeting along a line 13. When a second layer 14 is grown at least one “dump” is present in the first layer 15, but with a correct material combination and/or growth conditions, it is possible to fille the “dump” with the second layer 14.

Another solution can be to grow a thicker layer and when the thickness of the layer increases the extent of such islands will increase and eventually cover the whole substrate surface. However, thicker material layers may increase the cost of a material when the thickness increases and may influence other properties of a material, for example optical transparency.

A second layer 14 (refer FIG. 2) grown on top of the first layer 15 as exemplified above comprising GaSb, GaInSb, AlGaSb, AlInSb, GaAsSb, AlInAsSb, GaInAsSb, AlGaAsSb, or AlGaInAsSb has been demonstrated to be able to cover the first layer 15 and make the surface flat, i.e., having a TTV less than 10 μm. Further layers grown on top of the second layer has been demonstrated to have a flatter morphology.

A content of for example 60 at % Sb in the second layer is found to provide a flat morphology. Indium is also possible to add for lesser amounts of Sb to enable a flat morphology.

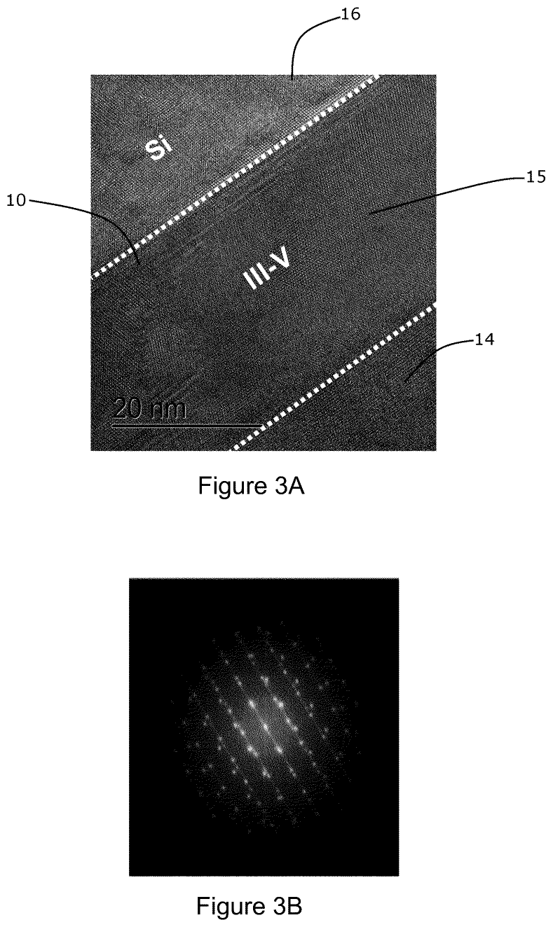

FIG. 3A is an electron microscope image of a (111)Si crystal having a first layer 15 comprising for example AlAsSb, wherein faults 10 are running in parallel with the (111)Si crystal surface. A second layer 14 comprising at least AlGaInAsSb is grown on top of the first layer 15 and none of the faults (threading dislocations and/or other faults) are propagating from the first layer 15.

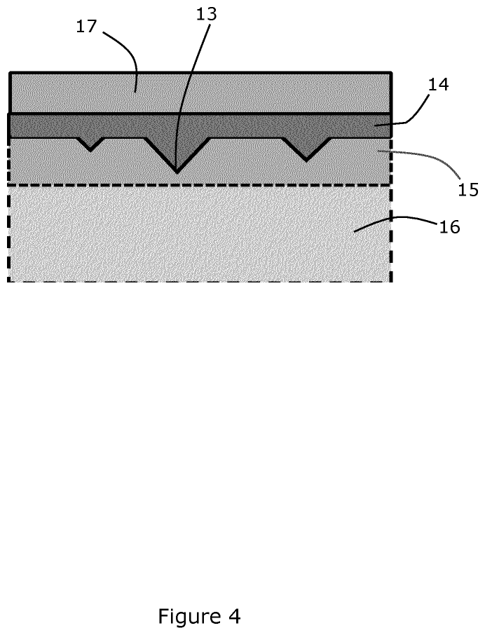

The example of an embodiment as illustrated in FIG. 4 comprises a third layer 17 which may be introduced comprising AlAsSb, AlInSb, AlInAsSb, AlInPSb, AIPSb, AlInAsPSb or AlAsPSb. The third layer 17 is grown with a lattice constant adapted to the lattice constant of the surface of the second layer 12, and afterwards the composition is adjusted to a lattice constant of interest.

The effect of growing on a Si(111) substrate with respect to fault propagation along lines parallel with the Si substrate surface is also valid for defects in the third layer 17. Therefore, the third layer 17 may be a thinner layer (<1 μm) and layers with lattice constant close to the lattice constant of or between GaAs, InAs and InP is possible.

A further question is how the respective lattice constants are relative to each other. The lattice constants of GaInAs and GaAsSb has lattice constants close to each other. Increasing the amount of Indium or Antimon results in lattice constants that are increasingly different from the lattice constant of GaAs.

Since GaAs, InAs, InSb, GaSb and InP substrates are frequently used in semiconductors a Si substrate with layers providing a lattice constant close to or between the lattice constant of GaAs, InAs, InSb, GaSb and InP without the use of thicker buffer layers (>1 μm) is a preferred solution to the lattice mismatch problem. Layers thinner than 1 μm is preferable as a buffer between the substrate and active device.

With reference to FIG. 4, a first layer 15 comprising for example AlGaInAsSb on top of a AlAsSb, or AlSb layer is used wherein a higher content of Sb is used in the AlGaInAsSb layer. The lattice constant can be adjusted in the AlAsSb and/or AlInAsSb layer and can be adjusted for example by adjusting the As content. A problem with the second layer 14 is that the content of Ga and Al is limited when As also is present. Decreasing the amount of Sb or In too fast can result in an uneven surfaces and an increased amount of defects.

Therefore, in this example the surface will have a lattice constant close to 6.1-6.0 Å, which is far from the lattice constant of GaAs (5,651 Å), InAs (6.05 Å), GaSb (6.096 Å), InSb (6.479 Å), and InP (5,869 Å).

One beneficial aspect of the disclosed embodiments is that structures like AlInAs solar cells allow for a broader adjustment of the Al amount such that a higher ban gap can be achieved. It is also possible to make further layers, for example a fourth, a fifth layer etc. on top of the third layer 17, wherein the lattice constant can be adjusted further.

It is also possible to add less amount of Gallium within a limit <10 at %. Higher content of Gallium may provide propagating defects in a manufactured material.

FIG. 4 illustrates a AlGalnAs solar cell on a Si (111) substrate. The structure utilizes the Si substrate as a solar cell and the III-V materials as another solar cell.

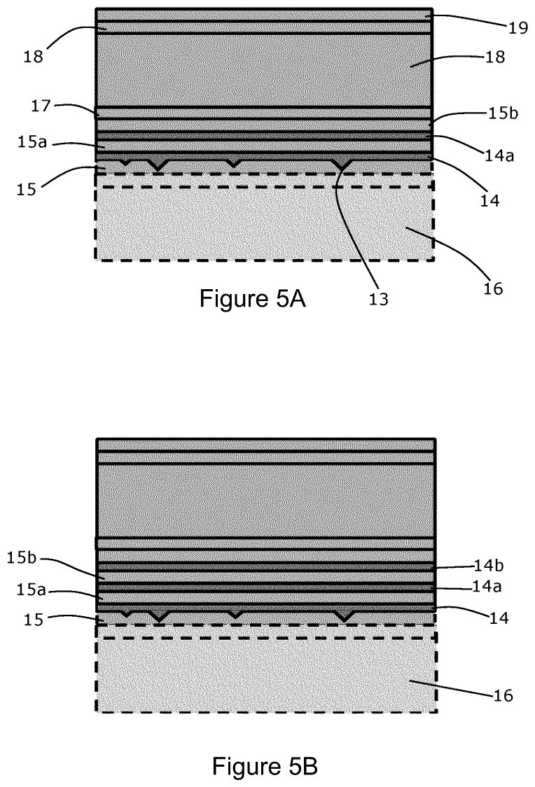

FIG. 5A illustrates a solar cell structure comprising two AlInAs solar cells on a Si (111) solar cell. One of the AlInAs solar cells is located on the top of the structure while the other AlInAs solar cell is located between the Si (111) solar cell and the top located solar cell. A layer of AlAsSb is located in between the two AlInAs solar cells thereby changing the lattice constant. The example illustrates therefore three different solar cells with different lattice constants for each collar cell.

FIG. 5B illustrate a repetition of further layers providing further solar cells.

Processing of a semiconductor material according to the disclosed embodiments is optionally performed at vacuum conditions. The growing of respective group III-V materials is done on a (111)Si substrates only.

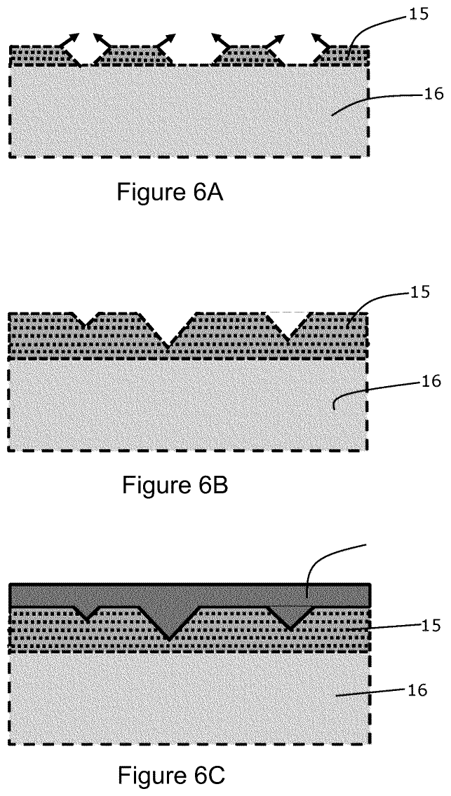

FIG. 6A illustrate how a first layer 15 is grown on a (111)Si surface, wherein a 3D growing happens, for example growing a thinner strained layer. When the layer is becoming thicker and growth conditions more 2D, the respective islands move towards each other as indicated by the respective arrows. The distance between the initial islands is random so when the islands are meeting each other the respective depths of the area between islands are varying (refer for example reference numeral 13 of FIG. 2).

This is illustrated in FIG. 6B. A further layer 14 can be added making the surface flatter as illustrated in FIG. 6C.

Manufacturing a material according to the disclosed embodiments may be done in a Molecular Beam Epitaxy (MBE) machine or similar machines growing group III-V materials on top of a Si substrate of 40-1000 μm thickness with a surface crystal plane of (111) orientation.

An MBE machine uses vacuum deposition with different material sources when manufacturing a sample material. Another variant of the MBE machine is the MEE machine which uses vacuum deposition, but respective material sources may be activated one by one and not always simultaneously.

Another example of a machine is the horizontal inline evaporation system (for example an MBE machine) which is a production system using vacuum deposition in combination with a conveyer belt moving through the machine. The configuration comprises usually different deposition zones for different layers of the material under production.

When vacuum deposition is done there might bee situations wherein only a part of a substrate surface should be subject to the vacuum deposition of a specific material. It is known to use a mask on top of a substrate surface masking areas of the substrate surface that should not be subject to a specific vacuum deposition.

The following non limiting examples of layers may be part of the present invention:
a first layer of 5-100 nm thickness comprising AlAs_{1-z}Sb_{z} on top of the Si substrate, wherein 1.0>=z>0 wherein z is gradually decreasing in the interval from the area close to the Si substrate,
a second layer of 1-100 nm thickness comprising Al_{1-x-y}GaxIn_{y}As_{1-z}Sb_{z} on top of the first layer, wherein 1.0>=x>0.6, 1.0>y>=0 and 1.0>=z>0,
a third layer of 1-100 nm thickness comprising Al_{1-y}In_{y}As_{1-z}Sb_{z}, wherein 0.9>y>=0 and 1.0>=z=>0 and z<1+y wherein z is decreasing in the interval form the area close to the second layer,
one or more active layers comprising GaAs, InAs, GaSb, AlSb, GaInAs, or AlInAs, or AlGaAs, or InAsSb, or AlInAsSb, or AlGaInAs, or GaAsSb, or GaInAsSb, or AlAsSb, or AlGaAsSb or AlGaInAsSb on top of the third layer.

Further, a first layer may be added with phosphorus providing AlAsPSb having a lattice constant in between 5.463 Å (AlP) and 6.136 Å (AlSb), or enabling a reduction of the As content needed to be added.

Further, a third layer may be added with phosphorus providing AlInAsPSb having a lattice constant in between 5.463 Å (AlP) and 6.479 Å (InSb), or is enabling a reduction of the As content that is needed to be added.

A second layer may also be added with phosphorus providing AlGaInAsPSb having a lattice constant in between 5.451 Å (GaP) and 6.479 Å (InSb) or enabling a reduction of the As content needed to be added.

A first layer may be added with Indium providing AlInAsSb having a lattice constant in between 5.660 Å (AlAs) and 6.479 Å (InSb)

A third layer may be added with Gallium providing AlInAsSb having a lattice constant in between 5.660 Å (AlAs) and 6.479 Å (InSb)

A second layer and a third layer may be repeated with thin layers (<100 nm) in a super lattice which changes the effective dielectric constant, the effective band gap and the light absorption of respective layers.

1-18. (canceled)

19. A method of manufacturing a semiconductor material, comprising the steps of:
(i) providing a silicon substrate having a thickness within an approximate range of 40-1000 μm and a surface on a (111) crystal plane or on less than 5 degrees off of the (111) crystal plane;
(ii) growing a first layer comprising III-V materials on top of the silicon substrate, wherein the layer is grown leaving multiple thicker grown islands connected via thinner sections of the first layer, the first layer having a thickness within an approximate range of 1-100 nm, and the thicker grown islands being grown with a gradient in their lattice constant providing a lattice constant of the first layer being different from the lattice of the final grown material, the difference in lattice constant between the first layer and the final grown material resulting in defect planes parallel to the (111) surface located below the grown islands, the defect planes providing strain relaxation of the final grown material; and
(iii) growing a second layer comprising III-V materials and having a thickness within an approximate range of 1-100 nm, thereby reducing a surface roughness compared to the final surface of the first layer.

20. The method of claim 19, comprising a step of growing a third layer comprising Al1-yInyAs1-zSbz on top of the second layer, the third layer having a thickness within an approximate range of 1-100 nm, wherein
y is within a range of 0-0.9,
z is within a range of 0-1.0,
z is less than (y+1),
z decreases in an interval from the area close to the second layer, and
one or more active layers comprising GaAs, InAs, GaSb, AlSb, GaInAs, AlInAs, AlGaAs, InAsSb, AlInAsSb, AlGaInAs, GaAsSb, GaInAsSb, AlAsSb, AlGaAsSb, or AlGaInAsSb are grown on top of the third layer.

21. The method of claim 19, wherein the first layer comprises AlAs1-zSbz and z is within a range of 0-1.0.

22. The method of claim 19, wherein
the first layer comprises Al1-yInyAs1-zSbz, and
y and z are each separately within a range of 0-1.0.

23. The method of claim 20, wherein the first layer is added with phosphorus in step (ii), thereby providing a material with a lattice constant in between 5.463 Å (AlP) and 6.136 Å (AlSb).

24. The method of claim 19, wherein
the second layer comprises Al1-xGaxAs1-zSbz, and
x and z are each separately within a range of 0-1.0.

25. The method of claim 19, wherein
the second layer comprises Al1-x-yGaxInyAs1-zSbz,
the sum of x and y is less than or equal to 1,
x and y are each greater than 0, and
z is within a range of 0-1.0.

26. The method of claim 23, wherein the second layer is added with phosphorus in step (iii), thereby providing a material having a lattice constant between 5.451 Å (GaP) and 6.479 Å (InSb).

27. The method of claim 24, wherein the second layer is added with phosphorus in step (iii), thereby providing a material having a lattice constant between 5.451 Å (GaP) and 6.479 Å (InSb).

28. The method of claim 19, wherein steps (ii) and (iii) for growing the first layer and second layer are repeated one or more times, which thereby provides a gradual strain relaxation.

29. The method of claim 19, wherein steps (i)-(iii) for manufacturing the semiconductor material are performed under vacuum pressure less than 1×10⁻⁴ Torr.

30. The method of claim 19, wherein steps (i)-(iii) for manufacturing the semiconductor material are performed under pressure greater than or equal to 1×10⁻⁴ Torr.

31. The method of claim 28, wherein steps (i)-(iii) for manufacturing the semiconductor material are performed with group III and group V materials in heated solid form or melted form.

32. The method of claim 29, wherein the steps (i)-(iii) for manufacturing the semiconductor material are performed with heated solid or melted sources as the source of group III materials, and hydrides as the source of group V materials.

33. The method of claim 30, wherein the steps (i)-(iii) for manufacturing the semiconductor material are performed with a combination of the respective sources of the group III and group V materials.

34. The method of claim 31, wherein the steps (i)-(iii) for manufacturing the semiconductor material are performed with a combination of the respective sources of the group III and group V materials.

35. The method of claim 28, wherein the steps (i)-(iii) for manufacturing the semiconductor material are performed in a Molecular Beam Epitaxy machine.

36. The method of claim 28, wherein the steps (i)-(iii) for manufacturing the semiconductor material are performed in an in-line horizontal deposition machine.

37. The method of claim 35, wherein the steps (i)-(iii) for manufacturing the semiconductor material are performed by moving the silicon substrate through several evaporation zones with different deposition methods.

38. A solar cell comprising a semiconductor material made by the method of claim 19.
